(19) United States
(12) Patent Application Publication
(10) Pub. No.: US 2025/0169219 A1
(43) Pub. Date: May 22, 2025

(54) IMAGE SENSOR

(71) Applicant: Samsung Electronics Co., Ltd., Suwon-si (KR)

(72) Inventors: Junghye Kim, Suwon-si (KR); Donghyun Kim, Suwon-si (KR); Sungin Kim, Suwon-si (KR)

(21) Appl. No.: 18/950,343

(22) Filed: Nov. 18, 2024

(30) Foreign Application Priority Data
Nov. 20, 2023 (KR) 10-2023-0161440

(51) Int. Cl. H01L 27/146; H01L 27/02

(52) U.S. Cl. CPC H10F 39/813; H10D 89/611; H10D 89/921; H10F 39/182; H10F 39/807; H10F 39/811

(57) ABSTRACT

An image sensor includes a substrate including a pixel region, a through electrode region, and a power supply region between the pixel region and the through electrode region, through electrodes in the through electrode region, shared pixels separated from each other by a first trench isolation structure in the pixel region and each shared pixel including unit pixels, wherein the first trench isolation structure extends in the substrate in a vertical direction, contact barriers arranged between the shared pixels and vertically overlapping the first trench isolation structure, and a protection diode arranged in the power supply region, including a first impurity region where first power is supplied by any one of the through electrodes, and electrically connected to the contact barriers.

### CROSS-REFERENCE TO RELATED APPLICATION

This application is based on and claims priority under 35 U.S.C. § 119 to Korean Patent Application No. 10-2023-0161440, filed on Nov. 20, 2023, in the Korean Intellectual Property Office, the disclosure of which is incorporated by reference herein in its entirety.

### BACKGROUND

The inventive concept relates to an image sensor, and more particularly, to an image sensor including shared pixels.

Image sensors are devices configured to convert optical image signals into electrical signals. An image sensor includes a plurality of unit pixels arranged in a two-dimensional array. In general, each unit pixel may include a light sensing element, such as a photodiode, and a plurality of pixel transistors. The image sensor further includes a pixel circuit configured to use charges generated by photodiodes of respective unit pixels and output them as pixel signals. As the integration level of image sensors has increased, each unit pixel has decreased in size. As described above, as pixel sizes continue to decrease, a shared pixel structure in which the unit pixels share transistors is applied to image sensors to increase the areas of the photodiodes.

### SUMMARY

The inventive concept provides an image sensor with a sharing pixel structure that improves electrical characteristics.

According to an aspect of the inventive concept, there is provided an image sensor including a substrate comprising a pixel region, a through electrode region, and a power supply region between the pixel region and the through electrode region; a plurality of through electrodes in the through electrode region; a plurality of shared pixels separated from each other by a first trench isolation structure in the pixel region, each shared pixel of the plurality of shared pixels comprising a plurality of unit pixels, wherein the first trench isolation structure extends in the substrate in a vertical direction; a plurality of contact barriers between the plurality of shared pixels and overlapping the first trench isolation structure in the vertical direction; and a protection diode in the power supply region, the protection diode comprising a first impurity region where first power is supplied by any one of the plurality of through electrodes, and the protection diode being electrically connected to the plurality of contact barriers, wherein, in a plan view, between a first shared pixel and a second shared pixel that are adjacent to each other among the plurality of shared pixels, each of the plurality of contact barriers is arranged between a first source follower gate of the first shared pixel and a second source follower gate of the second shared pixel.

According to another aspect of the inventive concept, there is provided an image sensor including a substrate comprising a pixel region, a through electrode region, and a power supply region between the pixel region and the through electrode region; a plurality of through electrodes in the through electrode region; a plurality of shared pixels separated from each other by a first trench isolation structure in the pixel region, each shared pixel of the plurality of shared pixels comprising a plurality of unit pixels, wherein the first trench isolation structure extends in the substrate in a vertical direction; a plurality of contact barriers between the plurality of shared pixels and overlapping the first trench isolation structure in the vertical direction; and a protection diode in the power supply region, the protection diode comprising a first impurity region where first power is supplied by any one of the plurality of through electrodes, and the protection diode being electrically connected to the plurality of contact barriers, wherein the plurality of shared pixels comprise a first shared pixel and a second shared pixel that are adjacent to each other, and each of the first shared pixel and the second shared pixel comprises a plurality of floating diffusion regions at different locations from each other and a plurality of source follower gates that are electrically connected to the plurality of floating diffusion regions, the plurality of source follower gates being arranged at different locations from each other, and in a plan view, each of the plurality of contact barriers is between one of the plurality of source follower gates of the first shared pixel and one of the plurality of source follower gates of the second shared pixel which face each other.

According to another aspect of the inventive concept, there is provided an image sensor including a substrate comprising a pixel region, a through electrode region, and a power supply region between the pixel region and the through electrode region; a plurality of shared pixels comprising, in the pixel region, a first shared pixel and a second shared pixel which are adjacent to each other in a first horizontal direction, wherein each of the first shared pixel and the second shared pixel comprises a first source follower gate, a second source follower gate, a third source follower gate, a first sub-pixel with four first unit pixels sharing a first floating diffusion region, and a second sub-pixel with four second unit pixels sharing a second floating diffusion region; a first trench isolation structure in the substrate and configured to divide the plurality of shared pixels in the pixel region; a plurality of through electrodes in the through electrode region; a plurality of contact barriers having long axes in a second horizontal direction perpendicular to the first horizontal direction, the plurality of contact barriers being between the plurality of shared pixels, and the plurality of contact barriers overlapping the first trench isolation structure in a vertical direction; and a protection diode arranged in the power supply region, the protection diode comprising a first impurity region where first power is supplied by any one of the plurality of through electrodes, and the protection diode being electrically connected to the plurality of contact barriers, wherein, in each of the first shared pixel and the second shared pixel, the first source follower gate and the second source follower gate face each other in the first horizontal direction and are on opposite sides of each of the first shared pixel and the second shared pixel in the first horizontal direction, and the first source follower gate and the third source follower gate face each other in the second horizontal direction and are on one side of each of the first shared pixel and the second shared pixel in the first horizontal direction, and each of the plurality of contact barriers is between the second source follower gate of the first shared pixel and the first source follower gate and the third source follower gate of the second shared pixel.

### BRIEF DESCRIPTION OF THE DRAWINGS

Embodiments will be more clearly understood from the following detailed description taken in conjunction with the accompanying drawings in which:

FIG. 1 is a block diagram showing a configuration of an image sensor according to embodiments;

FIG. 2 is a planar layout showing main portions of an image sensor, according to embodiments;

FIG. 3 is an example circuit diagram of an image sensor according to embodiments;

FIGS. 4A and 4B are a planar layout and a cross-sectional view, respectively, of an image sensor according to embodiments;

FIG. 5 is a cross-sectional view showing contact barrier structures and protection diodes included in an image sensor, according to embodiments;

FIG. 6 is a cross-sectional view for explaining an electrical connection of an image sensor, according to embodiments;

FIGS. 7A and 7B are a planar layout and a cross-sectional view, respectively, of an image sensor according to embodiments;

FIGS. 8A and 8B are a planar layout and a cross-sectional view, respectively, of an image sensor according to embodiments;

FIG. 9 is a planar layout and a cross-sectional view, respectively, of an image sensor according to embodiments;

FIG. 10 is an example circuit diagram of an image sensor according to embodiments;

FIGS. 11A and 11B are a planar layout and a cross-sectional view, respectively, of an image sensor according to embodiments;

FIG. 12 is a block diagram of an electronic device that includes a multi-camera module including an image sensor, according to embodiments;

FIG. 13 is a detailed block diagram of the camera module of FIG. 12; and

FIG. 14 is a block diagram showing a configuration of an image sensor, according to embodiments.

### DETAILED DESCRIPTION OF THE EMBODIMENTS

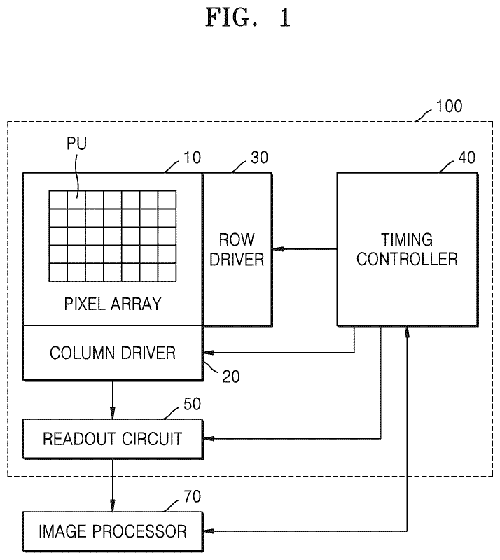

FIG. 1 is a block diagram showing a configuration of an image sensor according to embodiments.

Referring to FIG. 1, an image sensor 100 may include a pixel array 10 and a plurality of circuits configured to control the pixel array 10. In some embodiments, the plurality of circuits configured to control the pixel array 10 may include a column driver 20, a row driver 30, a timing controller 40, and a readout circuit 50.

The image sensor 100 may operate according to a control command from an image processor 70 and convert light from an external object into an electrical signal, thus outputting the electrical signal to the image processor 70. In some embodiments, the image sensor 100 may be a complementary metal oxide semiconductor (CMOS) image sensor.

The pixel array 10 may include a plurality of unit pixels PU having a two-dimensional array structure and arranged in a matrix form along row lines and column lines. In the present specification, the term “column (or row)” refers to a collection of unit pixels PU arranged in a horizontal direction, from among the unit pixels PU included in the pixel array 10, and the term “row (or column)” refers to a collection of unit pixels PU arranged in a vertical direction, from among the unit pixels PU included in the pixel array 10.

In some embodiments, each of the unit pixels PU may have a multi-pixel structure including a plurality of photodiodes. In each unit pixel PU, the photodiodes may generate charges by receiving light transmitted from the object. The image sensor 100 may perform auto-focusing based on a phase difference in pixel signals generated by the photodiodes included in each unit pixel PU. Each unit pixel PU may include a pixel circuit for generating the pixel signal from the charges generated by the photodiodes.

The column driver 20 may include a correlated double sampler, an analog-to-digital converter, and the like. The correlated double sampler may be connected, through column lines, to the unit pixels PU included in a row selected according to a row selection signal provided by the row driver 30, and may detect a reset voltage and a pixel voltage by performing correlated double sampling. The analog-to-digital converter may convert the reset voltage and the pixel voltage, which are detected by the correlated double sampler, into digital signals and transmit the digital signals to the readout circuit 50.

The readout circuit 50 may include a latch or a buffer circuit, an amplification circuit, and the like, which may temporarily store the digital signals, and may temporarily store or amplify the digital signals transmitted from the column driver 20, thereby generating image data. Operation timings of the column driver 20, the row driver 30, and the readout circuit 50 may be determined by the timing controller 40, and the timing controller 40 may be driven according to a control command transmitted from the image processor 70.

The image processor 70 may signal-process the image data output from the readout circuit 50 and output the image data to a display apparatus or store the same in a storage device, such as a memory. When the image sensor 100 is embedded in a self-driving car, the image processor 70 may signal-process the image data and transmit the same to a main controller that controls the self-driving car.

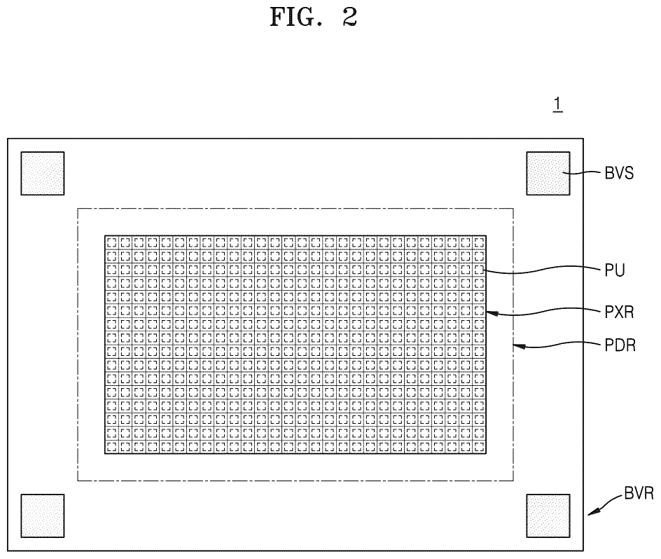

FIG. 2 is a planar layout showing main portions of an image sensor, according to embodiments.

Referring to FIG. 2, an image sensor 1 includes a pixel region PXR, a through electrode region BVR, and a power supply region PDR. In some embodiments, the pixel region PXR may include an active pixel region and a dark pixel region arranged to surround the active pixel region. A plurality of unit pixels PU are arranged in the pixel region PXR. The unit pixels PU are arranged in both the active pixel region and the dark pixel region, and configurations of the unit pixels PU in the active pixel region are substantially the same as those of the unit pixels PU in the dark pixel region; however, the unit pixels PU in the active pixel region may be used to obtain actual pixel information, while the unit pixels PU in the dark pixel region may be used to measure a dark current, wherein the dark pixel region may be covered by a light-shielding layer. The unit pixel PU in the dark pixel region may function as a reference pixel for the active pixel region and perform a function of automatically correcting a dark signal. For example, the light-shielding layer may block light from being incident to the unit pixel PU in the dark pixel region such that the reference charge amount, which may be generated in the unit pixel PU in the dark pixel region where light is blocked, may be measured, and by comparing the measured reference charge amount with the sensing charge amount generated in the unit pixel PU in the active pixel region, an optical signal input from the unit pixel PU in the active pixel region may be calculated based on a difference between the sensing charge amount and the reference charge amount.

In some embodiments, the through electrode region BVR and the power supply region PDR may be arranged along the periphery of the pixel region PXR. The through electrode region BVR is illustratively arranged on a side of the pixel region PXR (e.g., surrounding the pixel region PXR), and the power supply region PDR is illustratively arranged between the pixel region PXR and the through electrode region BVR, but one or more embodiments are not limited thereto. In some embodiments, the through electrode region BVR and the power supply region PDR may be arranged in different arbitrary portions along the periphery of the pixel region PXR.

The power supply region PDR of the image sensor 1 may refer to all portions excluding the pixel region PXR and the through electrode region BVR. In the power supply region PDR, circuits for processing power, control signals in the image sensor 1, and/or pixel signals obtained by the image sensor 1 and lines for connecting the circuits may be arranged.

A plurality of pads may be arranged near the pixel region PXR, and some of the pads may be DC pads supplied with DC power from the outside, while the others may be pads supplied with AC power, DC power, or control signals or exchanging data signals with the outside. The pads may be electrically connected to the lines in the power supply region PDR.

In the through electrode region BVR, a plurality of through electrode structures BVS may be arranged. The through electrode structure BVS may be referred to as a back via stack. The through electrode structures BVS may be configured to electrically connect the pads to the lines in the power supply region PDR. The lines in the power supply region PDR may electrically connect the through electrode structures BVS to the unit pixels PU and may be configured to distribute power from the through electrode structures BVS to the unit pixels PU.

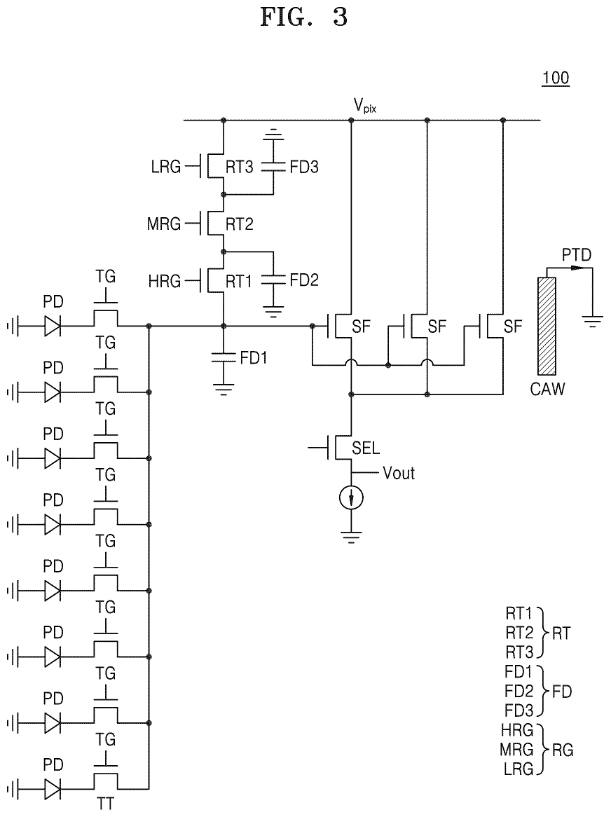

FIG. 3 is an example circuit diagram of an image sensor according to embodiments.

Referring to FIG. 3, the image sensor 100 may include a plurality of light sensing elements PD, a plurality of transmission transistors TT, a floating diffusion region FD, a reset transistor RT, a source follower transistor SF, and a selection transistor SEL. The light sensing element PD and the transmission transistor TT may form a unit pixel (PU of FIG. 1).

The transmission transistor TT, the reset transistor RT, the source follower transistor SF, and the selection transistor SEL may each include a transmission gate TG, a reset gate RG, a source follower gate, and a selection gate. In some embodiments, the transmission gate TG may be a vertical gate, and each of the reset gate RG, the source follower gate, and the selection gate may be a planar gate. The transmission gate TG may be arranged between the light sensing element PD and the floating diffusion region FD and transmit charges generated by the light sensing element PD to the floating diffusion region FD.

The transmission transistor TT may include the transmission gate TG and a source area and a drain area that are respectively connected to the floating diffusion region FD and the light sensing element PD. The reset transistor RT may include a source area connected to the reset gate RG and the floating diffusion region FD, and a drain area to which a power voltage Vpix is connected. The source follower transistor SF may include the source follower gate connected to the floating diffusion region FD, a source area connected to a source area of the selection transistor SEL, and a drain area to which the power voltage Vpix is connected. The selection transistor SEL may include the source area connected to the selection gate and the source area of the source follower transistor SF and a drain area to which an output voltage line Vout is connected.

In some embodiments, the reset transistor RT may include a first reset transistor RT1, a second reset transistor RT2, and a third reset transistor RT3 which include a high reset gate HRG, a middle reset gate MRG, and a low reset gate LRG and are connected in parallel, and the floating diffusion region FD may include a first floating diffusion region FD, a second floating diffusion region FD, and a third floating diffusion region FD which are connected to source areas of the first reset transistor RT1, the second reset transistor RT2, and the third reset transistor RT3, respectively. In some embodiments, the reset transistor RT may not include the second reset transistor RT2 and the third reset transistor RT3, and the floating diffusion region FD may not include the second floating diffusion region FD and the third floating diffusion region FD. In some embodiments, the image sensor 100 may include three or more source follower transistors SF connected in parallel.

In some embodiments, eight unit pixels including eight light sensing elements PD and eight transmission transistors TT may form a shared pixel sharing the floating diffusion region FD, the reset transistor RT, the source follower transistor SF, and the selection transistor SEL, but one or more embodiments are not limited thereto. The above shared pixel may be formed by four, six, or ten or more unit pixels.

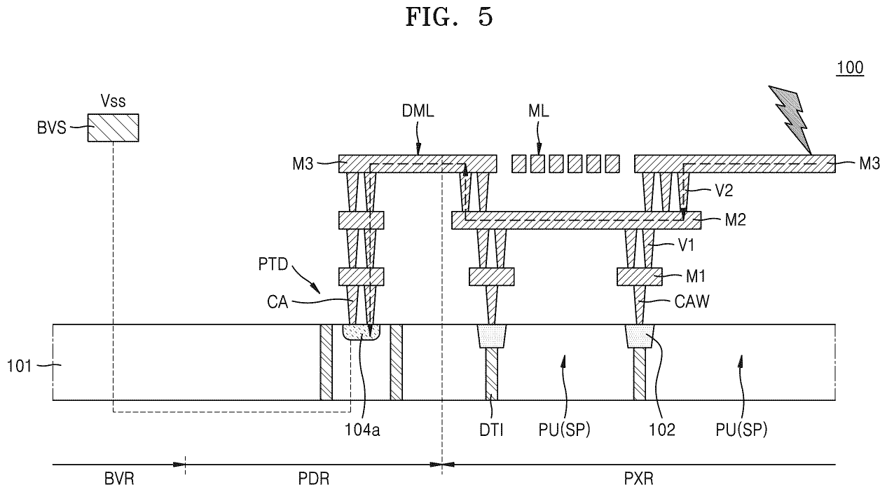

A contact barrier structure CAW may be arranged adjacent to the source follower transistor SF. For example, the image sensor 100 may include the shared pixels, and in a plan view, the contact barrier structure CAW may be arranged between the source follower transistors SF included in two adjacent shared pixels. The contact barrier structure CAW may be connected to a protection diode PTD. In some embodiments, the protection diode PTD may be arranged between the contact barrier structure CAW and the ground or between the contact barrier structure CAW and a negative power supply (Vss of FIG. 5).

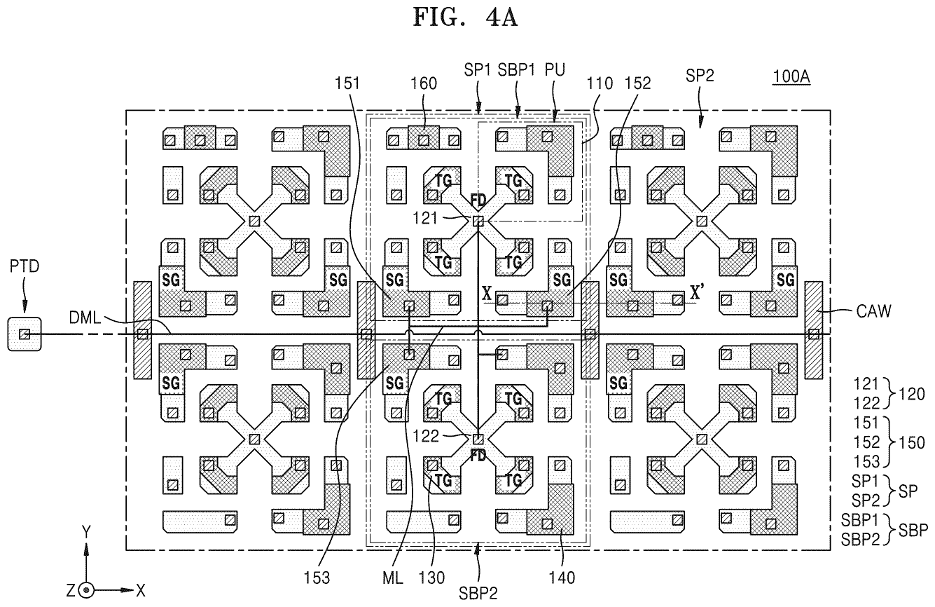

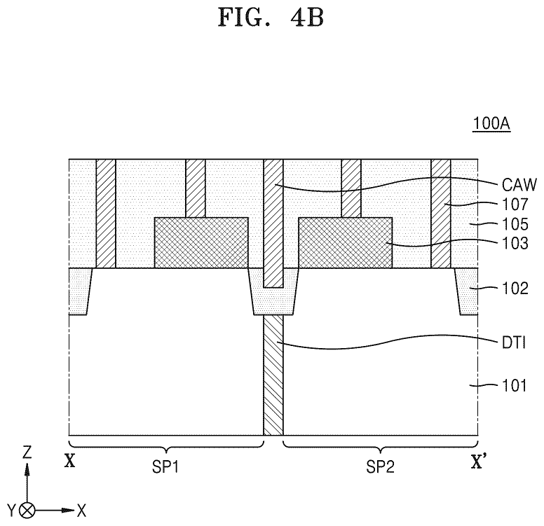

FIGS. 4A and 4B are a planar layout and a cross-sectional view, respectively, of an image sensor according to embodiments. In detail, FIG. 4A is a planar layout of an image sensor which corresponds to the circuit diagram of FIG. 3, and FIG. 4B is a cross-sectional view of the image sensor taken along a line X-X′ of FIG. 4A.

Referring to FIGS. 4A and 4B, an image sensor 100A may include a plurality of shared pixels SP arranged on a substrate 101 in a 2D array structure. The image sensor 100A may correspond to the circuit diagram of FIG. 3 regarding the image sensor 100.

Each shared pixel SP may include a plurality of unit pixels PU. In some embodiments, the shared pixel SP may include a photodiode 110, a floating diffusion region 120, a transmission transistor 130, various types of pixel transistors 140 to 160, and a pixel wiring layer ML. The pixel wiring layer ML may electrically connect the photodiode 110, the floating diffusion region 120, the transmission transistor 130, and various pixel transistors 140 to 160 which are included in the shared pixel SP to each other

The shared pixels SP may be separated from each other by a deep trench isolation structure DTI. In some embodiments, the deep trench isolation structure DTI may be a front-side deep trench isolation structure. The front-side deep trench isolation structure may extend from a front surface of the substrate 101 to the inside of the substrate 101 in a vertical direction (a Z direction). In addition, a plurality of photodiodes 110 may be arranged in each shared pixel SP. The photodiode 110 may be the light sensing element PD of FIG. 3.

The shared pixel SP may have a rectangular shape overall and include a region corresponding to one color filter (not shown). In other words, one identical color filter (not shown) may be arranged above all photodiodes 110 forming each individual shared pixel SP. Accordingly, light in the same wavelength range may be incident to all of the photodiodes 110 of the shared pixel SP. Each shared pixel SP may correspond to one color among red (R), blue (B), and green (G). Alternatively, each shared pixel SP may correspond to one color among cyan (C), yellow (Y), and magenta (M).

The shared pixel SP may include a plurality of sub-pixels SBP. The sub-pixel SBP may refer to a pixel in a range covered by a microlens (not shown). The microlens may include an organic material layer and an inorganic material layer that conformally covers a surface of the organic material layer. For example, the organic material layer may include TMR-based resin (Tokyo Ohka Kogyo, Co.) or MFR-based resin (Japan Synthetic Rubber Corporation). The sub-pixel SBP may include one unit pixel PU or a plurality of unit pixels PU.

In the image sensor 100A, each shared pixel SP may include two sub-pixels SBP. In addition, each sub-pixel SBP may include four unit pixels PU. That is, one shared pixel SP may include eight unit pixels PU. However, the number of sub-pixels SBP included in one shared pixel SP and the number of unit pixels PU in one sub-pixel SBP are not limited thereto.

The unit pixel PU may be a concept including the photodiode 110, the floating diffusion region 120, and the transmission transistor 130. Moreover, in a vertical configuration, the transmission transistor 130 and the pixel transistors 140 to 160 may be arranged on the surface of the substrate 101, and the photodiode 110 may be arranged under the surface of the substrate 101, for example, under the transmission transistor 130 and the pixel transistors 140 to 160. In some embodiments, the transmission transistor 130 may have a vertical gate structure and be connected to the photodiode 110. The transmission transistor 130 may be the transmission transistor TT of FIG. 3.

Each floating diffusion region 120 may be arranged at the center of each of a first sub-pixel SBP1 and a second sub-pixel SBP2. The floating diffusion regions 120 at different locations may be shared by all photodiodes 110 of the shared pixel SP through the pixel wiring layer ML. For example, the pixel wiring layer ML may be formed of or include a conductive material, such as tungsten (W), aluminum (Al), copper (Cu), tungsten silicide, titanium silicide, tungsten nitride, titanium nitride, and doped polysilicon. In other words, charges generated by all photodiodes 110 of the shared pixel SP may be stored in the floating diffusion region 120 and used as image signals. The floating diffusion region 120 may be the floating diffusion region FD of FIG. 3.

When the planar shape of the floating diffusion region 120 is described in detail, each floating diffusion region 120 may be surrounded by the deep trench isolation structure DTI that divides the unit pixels PU. Also, the floating diffusion regions 120 may contact each other in a silicon (Si) region of the substrate 101 with no deep trench isolation structure DTI that divides four unit pixels PU in the first sub-pixel SBP1 and the second sub-pixel SBP2, and may diagonally extend towards respective unit pixels PU within the respective sub-pixel SBP.

The shared pixel SP of the image sensor 100A may switch between a high-resolution mode and a high-sensitivity mode. Here, the term “high-resolution mode” refers to a mode in which optical sensing signals of each unit pixel PU or each of the first sub-pixel SBP1 and the second sub-pixel SBP2 are independently used, and the term “high-sensitivity mode” refers to a mode in which optical signals of the unit pixels PU forming the shared pixel SP are integrated.

That is, in the high-resolution mode, the charges generated by the photodiodes 110 of each unit pixel PU or each sub-pixel SBP in the shared pixel SP may pass the floating diffusion region 120 independently and be used as individual image signals. In the high-sensitivity mode, on the other hand, all charges generated by all of the photodiodes 110 of the unit pixels PU in the shared pixel SP may be accumulated in the floating diffusion region 120, and all of the charges may be used as one image signal.

In each unit pixel PU of the shared pixel SP, the transmission transistor 130 may be arranged. For example, when the shared pixel SP includes eight unit pixels PU, eight transmission transistors 130 may be arranged in the shared pixel SP. The transmission transistor 130 may be configured to transmit the charges generated by its corresponding photodiode 110 to the floating diffusion region 120. The transmission gate TG of the transmission transistor 130, the photodiode 110 corresponding to the transmission transistor 130, and the floating diffusion region 120 corresponding to the transmission transistor 130 may form the transmission transistor 130.

The shared pixel SP may include various types of pixel transistors 140 to 160 to transmit signals corresponding to the charges stored in the floating diffusion region 120. The pixel transistors 140 to 160 may include, for example, a reset transistor 140, a source follower transistor 150, and a selection transistor 160. The reset transistor 140, the source follower transistor 150, and the selection transistor 160 may be the reset transistor RT, the source follower transistor SF, and the selection transistor SEL of FIG. 3, respectively. A source follower gate SG of the source follower transistor 150 and high-density doping regions formed on both sides of the source follower gate SG may form the source follower transistor 150. The source follower transistor 150 is described in detail below.

In some embodiments, the shared pixel SP may further include a conversion gain transistor (not shown). The conversion gain transistor may be used to realize dual conversion gain or triple conversion gain of the shared pixel SP. Here, the term “conversion gain” refers to a ratio at which charges generated by the photodiode 110 move to the floating diffusion region 120 and are accumulated therein and the accumulated charges are converted into voltage.

In the image sensor 100A, each floating diffusion region 120 of the shared pixel SP may be connected to the source follower gate SG of the source follower transistor 150 through the pixel wiring layer ML. Such a connection relationship may be understood based on the circuit diagram of FIG. 3. For reference, the pixel wiring layer ML may be electrically connected to a component through a vertical contact 107.

The image sensor 100A may include the contact barrier structure CAW arranged between the shared pixels SP and overlapping the deep trench isolation structure DTI in the vertical direction (the Z direction). Shared pixels SP, which are aligned adjacent to each other in a first horizontal direction (an X direction) among the shared pixels SP, are referred to as a first shared pixel SP1 and a second shared pixel SP2 for convenience of explanation. That is, the shared pixel SP located in the middle in FIG. 4A is referred to as the first shared pixel SP1, and the shared pixel SP located on the right side of the first shared pixel SP1 is referred to as the second shared pixel SP2.

In detail, each of the first shared pixel SP1 and the second shared pixel SP2 may include a first floating diffusion region 121 and a second floating diffusion region 122 at different locations. In addition, each of the first shared pixel SP1 and the second shared pixel SP2 may include a plurality of source follower transistors 150 electrically connected to the first floating diffusion region 121 and the second floating diffusion region 122. The source follower transistors 150 may include a first source follower transistor 151, a second source follower transistor 152, and a third source follower transistor 153 that are at different locations. That is, to effectively realize a fine pixel structure, the image sensor 100A may have a configuration in which multiple source follower transistors 150 are arranged at different locations.

In some embodiments, the first source follower transistor 151 and the second source follower transistor 152 may be arranged in the first sub-pixel SBP1, and the third source follower transistor 153 may be arranged in the second sub-pixel SBP2. For example, the first source follower transistor 151 and the second source follower transistor 152 may face each other in the first horizontal direction (the X direction) and be arranged on opposite sides of the shared pixel SP in the first horizontal direction (the X direction), and the first source follower transistor 151 and the third source follower transistor 153 may face each other in the second horizontal direction (the Y direction) and be arranged on one side of the shared pixel SP in the first horizontal direction (the X direction).

In a plan view, the contact barrier structure CAW may have a long axis in the second horizontal direction (the Y direction) in regions where the second source follower transistor 152 of the first shared pixel SP1 faces the first source follower transistor 151 and the third source follower transistor 153 of the second shared pixel SP2.

In a cross-sectional view, the contact barrier structure CAW may overlap the deep trench isolation structure DTI in the vertical direction (the Z direction) and may be spaced apart therefrom. A lower insulating layer 102 that is an insulating material layer may be arranged between the contact barrier structure CAW and the deep trench isolation structure DTI. Here, the contact barrier structure CAW may extend into the lower insulating layer 102. That is, a vertical level of a lower (e.g., the lowermost) surface of the contact barrier structure CAW may be lower than a vertical level of a lower (e.g., the lowermost) surface of a gate structure 103 forming the source follower transistor 150. The gate structure 103 may include a gate electrode layer and a gate dielectric layer arranged between the gate electrode layer and the upper (e.g., the uppermost) surface of the substrate 101.

Each of the first source follower transistor 151, the second source follower transistor 152, and the third source follower transistor 153 may be electrically connected to the vertical contact 107, and the vertical contact 107 may be surrounded by an upper insulating layer 105.

The contact barrier structure CAW may be formed of or include a conductive metal material, such as, Cu, Al, or W. In some embodiments, the vertical contact 107 may be formed of or include the same material as the contact barrier structure CAW. For example, the vertical contact 107 may include a conductive metal material, such as Cu, Al, or W. As described below, the contact barrier structure CAW and the vertical contact 107 may be formed of substantially the same material through substantially the same process. The contact barrier structure CAW including the aforementioned conductive metal material may be electrically connected to a DC voltage line (not shown). Accordingly, the contact barrier structure CAW may hinder coupling between neighboring source follower gates SG.

As the integration level of the image sensor increases, the size of each pixel decreases. As described above, as pixel sizes continue to decrease, a shared pixel structure in which pixels share transistors is applied to the image sensor to increase the areas of the photodiodes.

In the case of a general image sensor, parasitic capacitance may be generated because of coupling occurring between source follower gates included in neighboring shared pixels. Such generation may result in the undesired degradation in electrical characteristics. To restrict the generation of parasitic capacitance, it is advisable to increase a gap between source follower gates of neighboring shared pixels to the maximum extent, but the freedom degree for the arrangement of the source follower gates in a fine pixel structure is highly limited.

Therefore, to solve the problem regarding the parasitic capacitance, in the image sensor 100A according to the present embodiment, the contact barrier structure CAW is arranged between the source follower gates SG and a voltage is applied to thereby restrict the generation of parasitic capacitance. That is, the contact barrier structure CAW is arranged between neighboring shared pixels SP to overlap the deep trench isolation structure DTI in the vertical direction (the Z direction). The generation of parasitic capacitance between the source follower gates SG may be effectively prevented.

The contact barrier structures CAW individually arranged between the shared pixels SP may be electrically connected to each other through a discharging wiring layer DML. For example, the discharging wiring layer DML may be formed of or include a conductive material, such as W, Al, Cu, tungsten silicide, titanium silicide, tungsten nitride, titanium nitride, and doped polysilicon. The pixel wiring layer ML and the discharging wiring layer DML may be formed of substantially the same material through substantially the same process. The discharging wiring layer DML may not be electrically connected to the pixel wiring layer ML. In some embodiments, the discharging wiring layer DML may extend in the first horizontal direction (the X direction) and may be electrically connected to the contact barrier structures CAW.

The discharging wiring layer DML may electrically connect the protection diode PTD to the contact barrier structures CAW. The pixel wiring layer ML and the contact barrier structures CAW, which are connected to the unit pixels PU, are not electrically connected to the discharging wiring layer DML, and thus, a voltage different from that applied to the unit pixels PU may be applied to the contact barrier structures CAW. Also, because the contact barrier structures CAW are connected to the protection diodes PTD, the charges generated in the pixel wiring layer ML and the discharging wiring layer DML during the process of forming the pixel wiring layer ML and the discharging wiring layer DML may be discharged through the protection diodes PTD. The contact barrier structure CAW and the protection diode PTD may be the contact barrier structure CAW and the protection diode PTD of FIG. 3, respectively.

The image sensor 100A may include the contact barrier structures CAW configured to restrict the occurrence of coupling between the source follower gates SG of neighboring shared pixels SP, and thus, the electrical characteristics of the image sensor 100A may be improved. Moreover, the image sensor 100A according to an embodiment includes the discharging wiring layer DML, which electrically connects the contact barrier structures CAW to the protection diode PTD and is not electrically connected to the pixel wiring layer ML electrically connected to the shared pixels SP, and thus, plasma-induced damage to the image sensor 100A during the process of forming the pixel wiring layer ML and the discharging wiring layer DML may be prevented.

FIG. 5 is a cross-sectional view showing contact barrier structures and protection diodes included in an image sensor, according to embodiments.

Referring to FIG. 5, the image sensor 100 includes a pixel region PXR, a power supply region PDR, and a through electrode region BVR. In the pixel region PXR, a plurality of unit pixels PU are arranged. The unit pixels PU may form a plurality of shared pixels SP each including a plurality of unit pixels PU. In some embodiments, the power supply region PDR may be between the pixel region PXR and the through electrode region BVR.

The image sensor 100 may include the substrate 101 including the pixel region PXR, the power supply region PDR, and the through electrode region BVR, the lower insulating layer 102, and the deep trench isolation structure DTI. The shared pixels SP may be separated from each other by the deep trench isolation structure DTI in the pixel region PXR. The image sensor 100 may include the protection diode PTD in the power supply region PDR and the through electrode structure BVS in the through electrode region BVR.

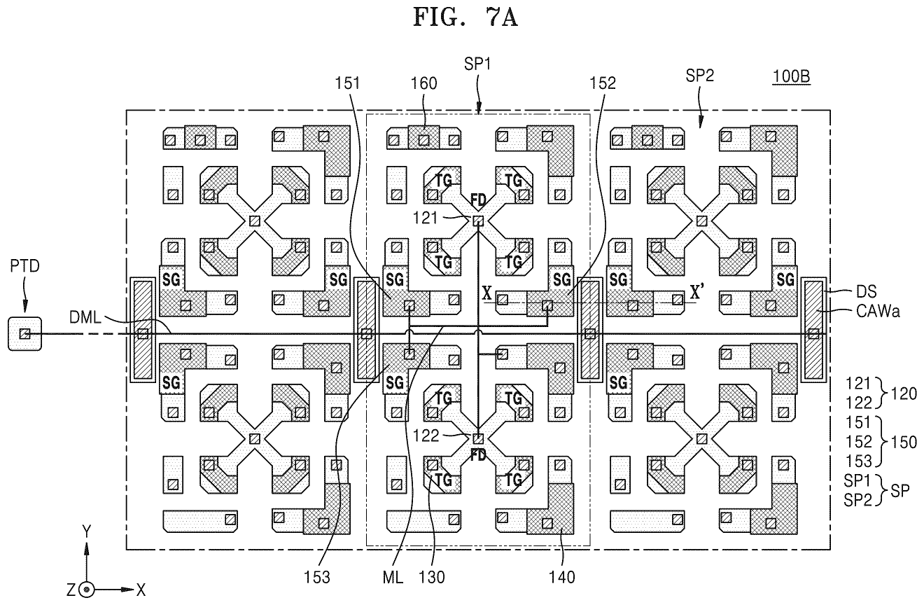

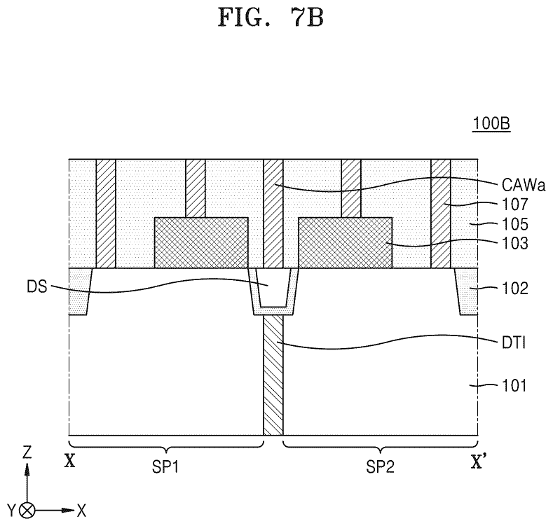

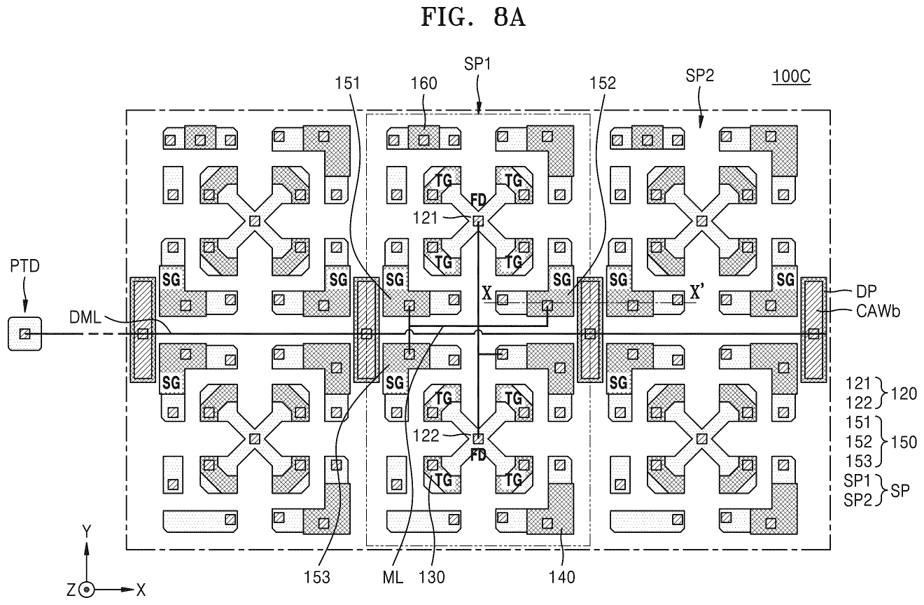

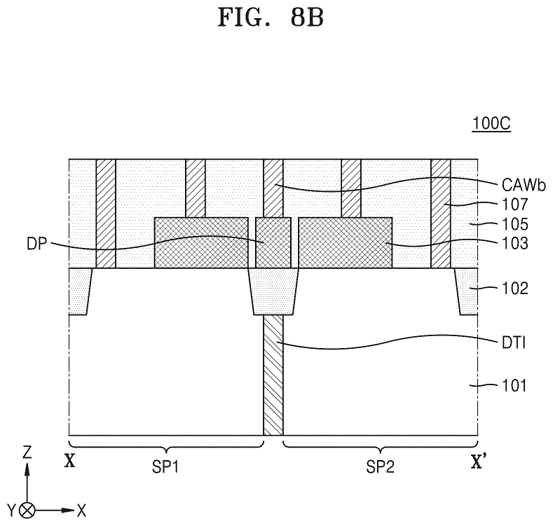

In the pixel region PXR, the contact barrier structures CAW may be arranged. Respective contact barrier structures CAW may be arranged between two adjacent shared pixels SP. The contact barrier structure CAW may vertically overlap the deep trench isolation structure DTI and may be spaced apart therefrom. The lower insulating layer 102 may be arranged between the contact barrier structure CAW and the deep trench isolation structure DTI. FIG. 5 shows that a lower surface of the contact barrier structure CAW contacts an upper surface of the lower insulating layer 102, but one or more embodiments are not limited thereto. For example, as shown in FIG. 4B, the contact barrier structure CAW may extend into the lower insulating layer 102, or as shown in FIG. 7B, the lower insulating layer 102 and a silicon dummy structure DS, which include different materials, may be arranged between a contact barrier structure CAWa and the deep trench isolation structure DTI, or as shown in FIG. 8B, the lower insulating layer 102 and a conductive dummy structure DP, which include different materials, may be arranged between a contact barrier structure CAWb and the deep trench isolation structure DTI.

The pixel wiring layer ML and the discharging wiring layer DML may be formed by a plurality of wiring patterns M1 to M3, a plurality of via patterns V1 and V2, and a vertical contact CA. The vertical contact CA may be the vertical contact 107 of FIG. 4B. However, embodiments are not limited thereto, and the vertical contact CA may be positioned in the power supply region PDR instead of or in addition to in the pixel region PXR. The discharging wiring layer DML may not be electrically connected to the pixel wiring layer ML. The wiring patterns M1 to M3 may include a first wiring pattern M1, a second wiring pattern M2, and a third wiring pattern M3 which are sequentially positioned at different vertical levels away from the substrate 101 in the vertical direction, but one or more embodiments are not limited thereto. For example, the wiring patterns M1 to M3 may further include a fourth wiring pattern, a fifth wiring pattern, and a sixth wiring pattern which are sequentially at different vertical levels in the vertical direction above the third wiring pattern M3. The via patterns V1 and V2 may include a first via pattern V1 and a second via pattern V2 which are sequentially at different vertical levels from the substrate 101 in the vertical direction, but one or more embodiments are not limited thereto. For example, the via patterns V1 and V2 may further include a third via pattern, a fourth via pattern, and a fifth via pattern which are sequentially at different vertical levels in the vertical direction above the second via pattern V2. Each of the vertical contact CA and the contact barrier structure CAW may be connected under the first wiring pattern M1. The first via pattern V1 may connect between the first wiring pattern M1 to the second wiring pattern M2, and the second via pattern V2 may connect between the second wiring pattern M2 to the third wiring pattern M3. The third via pattern may connect the third wiring pattern M3 to the fourth wiring pattern, the fourth via pattern may connect the fourth wiring pattern to the fifth wiring pattern, and the fifth via pattern may connect the fifth wiring pattern to the sixth wiring pattern.

The discharging wiring layer DML may electrically connect the contact barrier structure CAW to a first impurity region 104a. In some embodiments, the discharging wiring layer DML may be formed by the first wiring pattern M1, the first via pattern V1, the second wiring pattern M2, the second via pattern V2, and the third wiring pattern M3 which are arranged between the contact barrier structure CAW and the protection diode PTD. The protection diode PTD may be formed by the vertical contact CA connected to the first wiring pattern M1, and the first impurity region 104a. The first impurity region 104a may be formed by injecting impurities of a first conductive type into the substrate 101. For example, the first conductive type may be an n type, and the first impurity region 104a may be an n-type impurity region. For example, the impurities of the first conductive type may be formed of or include one or more of nitrogen (N), phosphorus (P), arsenic (As), antimony (Sb), bismuth (Bi), sulfur(S), selenium (Se), tellurium (Te), and polonium (Po).

In some embodiments, negative power Vss may be supplied to the first impurity region 104a by the through electrode structure BVS. In some embodiments, the ground may be provided to the first impurity region 104a. A portion of the substrate 101, in which the first impurity region 104a is arranged, may be separated from another portion of the substrate 101 by the deep trench isolation structure DTI.

The deep trench isolation structure DTI dividing respective shared pixels SP in the pixel region PXR may be referred to as a first trench isolation structure, and the deep trench isolation structure DTI dividing, in the power supply region PDR, the portion of the substrate 101 with the first impurity region 104a from another portion of the substrate 101 may be referred to as a second trench isolation structure.

Because the image sensor 100 includes the discharging wiring layer DML that electrically connects the contact barrier structure CAW to the protection diode PTD and is not electrically connected to the pixel wiring layer ML, plasma-induced damage to the image sensor 100 during the process of forming the pixel wiring layer ML and the discharging wiring layer DML may be prevented.

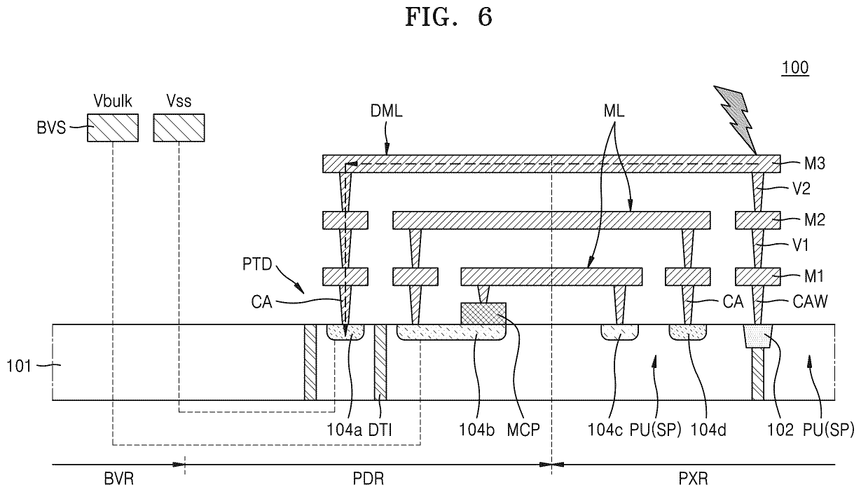

FIG. 6 is a cross-sectional view for explaining an electrical connection of an image sensor, according to embodiments. In FIG. 6, the description already provided with reference to FIG. 5 may be omitted.

Referring to FIG. 6, the image sensor 100 includes the pixel region PXR, the power supply region PDR, and the through electrode region BVR. In the pixel region PXR, a plurality of unit pixels PU are arranged. The unit pixels PU may form a plurality of shared pixels SP each including a plurality of unit pixels PU. In some embodiments, the power supply region PDR may be between the pixel region PXR and the through electrode region BVR.

The image sensor 100 may include the substrate 101, the lower insulating layer 102, and the deep trench isolation structure DTI. The shared pixels SP may be separated from each other by the deep trench isolation structure DTI in the pixel region PXR. The image sensor 100 may include the protection diode PTD in the power supply region PDR and the through electrode structures BVS in the through electrode region BVR.

In the pixel region PXR, the contact barrier structures CAW may be arranged. Respective contact barrier structures CAW may be arranged between two adjacent shared pixels SP. The contact barrier structure CAW may vertically overlap the deep trench isolation structure DTI and may be spaced apart therefrom. The lower insulating layer 102 may be arranged between the contact barrier structure CAW and the deep trench isolation structure DTI.

The pixel wiring layer ML and the discharging wiring layer DML may be formed by a plurality of wiring patterns M1 to M3, a plurality of via patterns V1 and V2, and a vertical contact CA. The discharging wiring layer DML may not be electrically connected to the pixel wiring layer ML.

The discharging wiring layer DML may electrically connect the contact barrier structure CAW to the first impurity region 104a. The pixel wiring layer ML may be arranged between a second impurity region 104b and a third impurity region 104c and electrically connect the second impurity region 104b to a fourth impurity region 104d. The first impurity region 104a may be formed by injecting impurities of a first conductive type into the substrate 101, and the second impurity region 104b may be formed by injecting impurities of a second conductive type into the substrate 101. The first impurity region 104a and the second impurity region 104b may be located in the power supply region PDR. For example, the first conductive type may be an n type, the second conductive type may be a p type, the first impurity region 104a may be an n-type impurity region, and the second impurity region 104b may be a p-type impurity region. For example, the impurities of the second conductive type may be formed of or include one or more of boron (B), aluminum (Al), gallium (Ga), indium (In), thallium (TI), zinc (Zn), cadmium (Cd), and mercury (Hg). In some embodiments, negative power Vss may be supplied to the first impurity region 104a by the through electrode structure BVS, and different power, e.g., bulk power Vbulk, from that supplied to the first impurity region 104a may be supplied to the second impurity region 104b. The bulk power Vbulk may be supplied to the transmission transistor 130 and the pixel transistors 140 to 160 of FIG. 4A as a body bias. The first impurity region 104a and the second impurity region 104b may be separated from each other by the deep trench isolation structure DTI.

The third impurity region 104c and the fourth impurity region 104d may be arranged in the pixel region PXR. The third impurity region 104c and the fourth impurity region 104d may be formed by injecting impurities of different conductive types into the substrate 101. In some embodiments, the third impurity region 104c may be a p-type impurity region, and the fourth impurity region 104d may be an n-type impurity region.

The third impurity region 104c may be configured to supply the body bias to the transmission transistor 130 and the pixel transistors 140 to 160 of FIG. 4A. The fourth impurity region 104d may be a drain area of at least one of the transmission transistor 130 and the pixel transistors 140 to 160 of FIG. 4A. A MOS capacitor structure MCP may be arranged between the pixel wiring layer ML and the second impurity region 104b. The MOS capacitor structure MCP may include a gate electrode layer and a gate dielectric layer arranged between the gate electrode layer and an upper surface of the second impurity region 104b.

The vertical contacts CA may be respectively connected to the first impurity region 104a, the second impurity region 104b, the MOS capacitor structure MCP in the second impurity region 104b, the third impurity region 104c, and the fourth impurity region 104d.

Because the image sensor 100 includes the discharging wiring layer DML that electrically connects the contact barrier structure CAW to the protection diode PTD and is not electrically connected to the pixel wiring layer ML, plasma-induced damage to the unit pixels PU electrically connected to the pixel wiring layer ML, which may be caused during the process of forming the pixel wiring layer ML and the discharging wiring layer DML, may be prevented.

FIGS. 7A and 7B are a planar layout and a cross-sectional view, respectively, of an image sensor according to embodiments. In detail, FIG. 7A is a planar layout of an image sensor which corresponds to the circuit diagram of FIG. 3, and FIG. 7B is a cross-sectional view of the image sensor) taken along a line X-X′ of FIG. 7A. In FIGS. 7A and 7B, the descriptions already provided with reference to FIGS. 4A and 4B are omitted.

Referring to FIGS. 7A and 7B together, an image sensor 100B may include a plurality of shared pixels SP arranged on a substrate 101 in a 2D array structure. The image sensor 100B according to the present embodiment may include a contact barrier structure CAWa arranged between the shared pixels SP and overlapping the deep trench isolation structure DTI in the vertical direction (the Z direction).

In a plan view, the contact barrier structure CAWa may have a long axis in the second horizontal direction (the Y direction) in regions where the second source follower transistor 152 of the first shared pixel SP1 faces the first source follower transistor 151 and the third source follower transistor 153 of the second shared pixel SP2.

In a cross-sectional view, the contact barrier structure CAWa may overlap the deep trench isolation structure DTI in the vertical direction (the Z direction), and a silicon dummy structure DS may be arranged between the contact barrier structure CAWa and the deep trench isolation structure DTI. In some embodiments, a material forming the silicon dummy structure DS may be the same as that forming the substrate 101. That is, the lower insulating layer 102 and the silicon dummy structure DS, which include different materials, may be arranged between the contact barrier structure CAWa and the deep trench isolation structure DTI. Accordingly, a vertical level of a lower surface of the contact barrier structure CAWa may be substantially the same as the vertical level of the lower surface of the gate structure 103 forming the source follower transistor 150 and a vertical level of the upper surface of the substrate 101.

The discharging wiring layer DML may electrically connect the protection diode PTD to the contact barrier structures CAWa. The pixel wiring layer ML and the contact barrier structures CAWa, which are connected to the unit pixels PU, are not electrically connected to the discharging wiring layer DML, and thus, a voltage different from that applied to the unit pixels PU may be applied to the contact barrier structures CAWa.

FIGS. 8A and 8B are a planar layout and a cross-sectional view, respectively, of an image sensor according to embodiments. In detail, FIG. 8A is a planar layout of an image sensor which corresponds to the circuit diagram of FIG. 3, and FIG. 8B is a cross-sectional view of the image sensor taken along a line X-X′ of FIG. 8A. In FIGS. 8A and 8B, the descriptions already provided with reference to FIGS. 4A and 4B are omitted.

Referring to FIGS. 8A and 8B together, an image sensor 100C according to the present embodiment may include a plurality of shared pixels SP arranged on a substrate 101 in a 2D array structure.

The image sensor 100C according to the present embodiment may include a contact barrier structure CAWb arranged between the shared pixels SP and overlapping the deep trench isolation structure DTI in the vertical direction (the Z direction).

In a plan view, the contact barrier structure CAWb may have a long axis in the second horizontal direction (the Y direction) in regions where the second source follower transistor 152 of the first shared pixel SP1 faces the first source follower transistor 151 and the third source follower transistor 153 of the second shared pixel SP2.

In a cross-sectional view, the contact barrier structure CAWb may overlap the deep trench isolation structure DTI in the vertical direction (the Z direction), and a conductive dummy structure DP may be arranged between the contact barrier structure CAWb and the deep trench isolation structure DTI. For example, the conductive dummy structure DP may be formed of or include polysilicon. In some embodiments, a material forming the conductive dummy structure DP may be the same as that forming at least a portion of the gate structure 103. For example, the material forming the conductive dummy structure DP may be the same as the material forming the gate electrode layer of the gate structure 103. Alternatively, the conductive dummy structure DP may include the gate electrode layer and the gate dielectric layer arranged between the gate electrode layer and the upper surface of the lower insulating layer 102, like the gate structure 103. That is, the lower insulating layer 102 and the conductive dummy structure DP, which are formed of at least partially different materials, may be arranged between the contact barrier structure CAWb and the deep trench isolation structure DTI. Accordingly, a vertical level of a lower (e.g., the lowermost) surface of the contact barrier structure CAWb may be higher than a vertical level of the lower (e.g., the lowermost) surface of the gate structure 103 forming the source follower transistor 150 and the vertical level of the upper (e.g., the uppermost) surface of the substrate 101. In some embodiments, the vertical level of the lower (e.g., the lowermost) surface of the contact barrier structure CAWb may be the same as a vertical level of the upper (e.g., the uppermost) surface of the gate structure 103 forming the source follower transistor 150.

The discharging wiring layer DML may electrically connect the protection diode PTD to the contact barrier structures CAWb. The pixel wiring layer ML and the contact barrier structures CAWb, which are connected to the unit pixels PU, are not electrically connected to the discharging wiring layer DML, and thus, a voltage different from that applied to the unit pixels PU may be applied to the contact barrier structures CAWb.

In the image sensor 100C, the contact barrier structure CAWb and the conductive dummy structure DP are electrically connected to each other and form one shielding layer, and thus, the generation of parasitic capacitance between neighboring source follower gates SG may be effectively restricted.

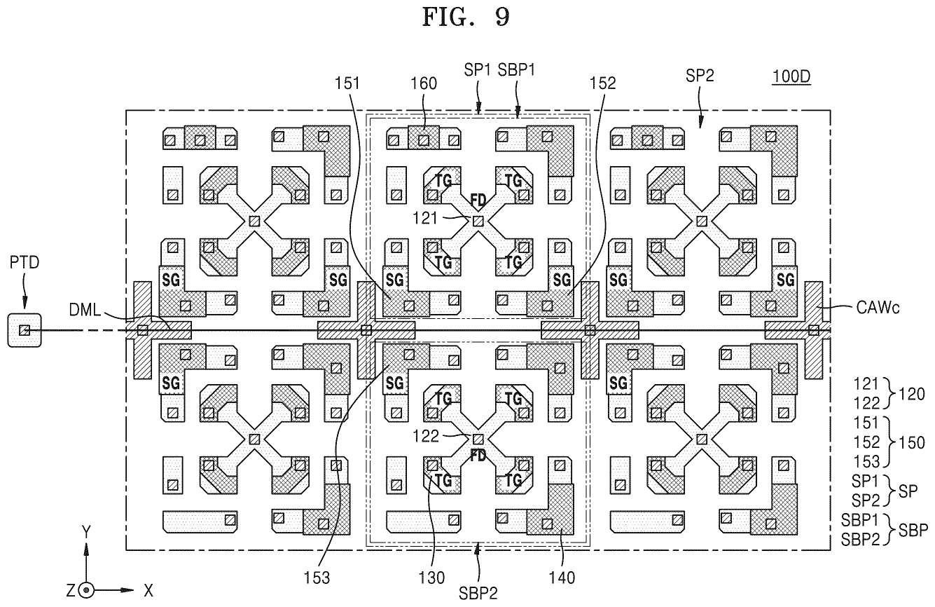

FIG. 9 is a planar layout and a cross-sectional view of an image sensor according to embodiments. In detail, FIG. 9 is a planar layout of the image sensor corresponding to the circuit diagram of FIG. 3. In FIG. 9, the descriptions already provided with reference to FIGS. 4A and 4B are omitted.

Referring to FIG. 9, an image sensor 100D according to the present embodiment may include a plurality of shared pixels SP arranged on a substrate 101 in a 2D array structure.

The image sensor 100D according to the present embodiment may include a contact barrier structure CAWc arranged between the shared pixels SP and the sub-pixels SBP and overlapping the deep trench isolation structure DTI in the vertical direction (the Z direction).

In the image sensor 100D according to the present embodiment, the first sub-pixel SBP1 and the second sub-pixel SBP2 may not share the floating diffusion region 120. That is, because the image sensor 100D does not include a pixel wiring layer electrically connecting the first floating diffusion region 121 of the first sub-pixel SBP1 to the second floating diffusion region 122 of the second sub-pixel SBP2, the first floating diffusion region 121 of the first sub-pixel SBP1 may not be electrically connected to the second floating diffusion region 122 of the second sub-pixel SBP2.

In a plan view, the contact barrier structures CAWc may be arranged in a cross shape in a region where the second source follower transistor 152 of the first shared pixel SP1 faces the first source follower transistor 151 and the third source follower transistor 153 of the second shared pixel SP2 and in a region where the first source follower transistor 151 of the first sub-pixel SBP1 faces the third source follower transistor 153 of the second sub-pixel SBP2. The cross-shaped contact barrier structure CAWc may also extend to a region between the first sub-pixel SBP1 and the second sub-pixel SBP2 that is adjacent to the second source follower transistor 152 of the first sub-pixel SBP1.

Although not separately shown, the image sensor 100D may further include the silicon dummy structure DS of FIGS. 7A and 7B or the conductive dummy structure DP of FIGS. 8A and 8B between the contact barrier structure CAWc and the lower insulating layer 102.

The discharging wiring layer DML may electrically connect the protection diode PTD to the contact barrier structures CAWc. The pixel wiring layer ML, which is connected to the unit pixels PU, is not electrically connected to the discharging wiring layer DML, and thus, a voltage different from that applied to the unit pixels PU may be applied to the contact barrier structures CAWc.

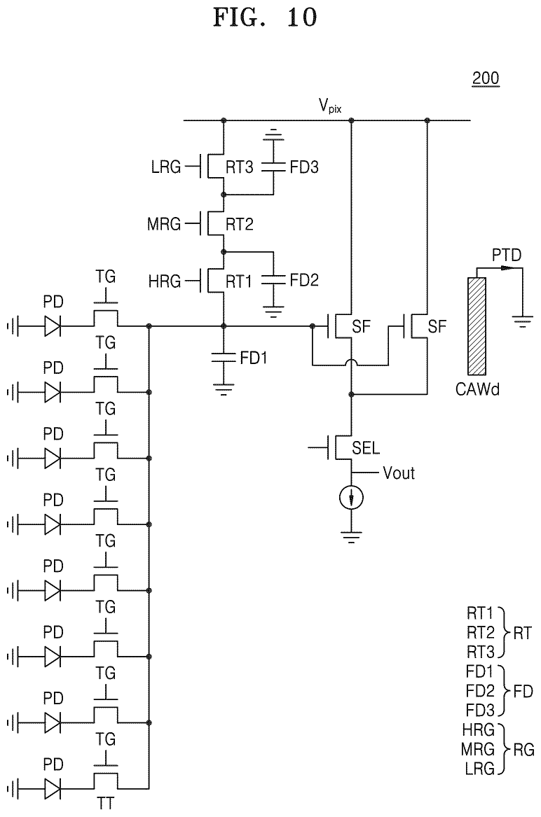

FIG. 10 is an example circuit diagram of an image sensor according to embodiments. In FIG. 10, the description already provided with reference to FIG. 3 may be omitted.

Referring to FIG. 10, an image sensor 200 may include a plurality of light sensing elements PD, a plurality of transmission transistors TT, a floating diffusion region FD, a reset transistor RT, a source follower transistor SF, and a selection transistor SEL. The light sensing element PD and the transmission transistor TT may form a unit pixel (PU of FIG. 1). In some embodiments, the image sensor 200 may include two source follower transistors SF connected in parallel.

A contact barrier structure CAWd may be arranged adjacent to the source follower transistor SF. For example, the image sensor 200 may include a plurality of shared pixels, and the contact barrier structure CAWd may be arranged between the source follower transistors SF included in two adjacent ones of the shared pixels. The contact barrier structure CAWd may be connected to a protection diode PTD.

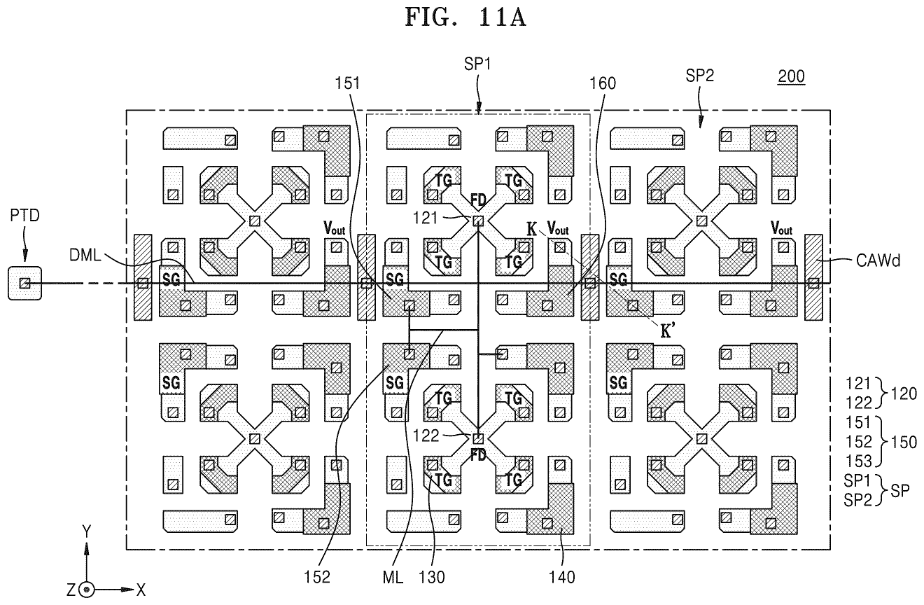

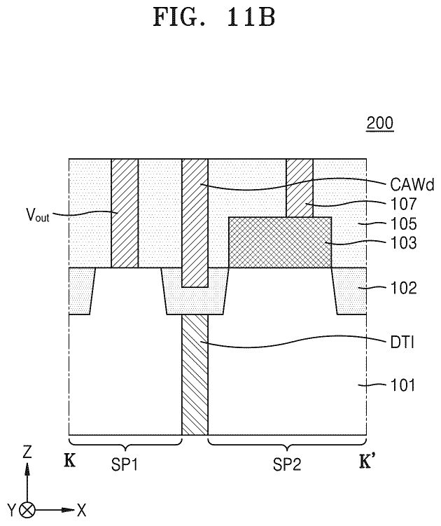

FIGS. 11A and 11B are a planar layout and a cross-sectional view, respectively, of an image sensor according to embodiments. In detail, FIG. 11A is a planar layout of an image sensor which corresponds to the circuit diagram of FIG. 10, and FIG. 11B is a cross-sectional view of the image sensor taken along a line K-K′ of FIG. 11A. In FIGS. 11A and 11B, the descriptions already provided with reference to FIGS. 4A and 4B are omitted.

Referring to FIGS. 11A and 11B together, the image sensor 200 according to the present embodiment may include a plurality of shared pixels SP arranged on a substrate 101 in a 2D array structure. The shared pixel SP may include various types of pixel transistors 140 to 160 to transmit signals corresponding to the charges stored in the floating diffusion region 120.

The image sensor 200 may include a contact barrier structure CAWd arranged between the shared pixels SP and overlapping the deep trench isolation structure DTI in the vertical direction (the Z direction).

In detail, each of the first shared pixel SP1 and the second shared pixel SP2 may include a first floating diffusion region 121 and a second floating diffusion region 122 at different locations. In addition, each of the first shared pixel SP1 and the second shared pixel SP2 may include a plurality of source follower transistors 150 respectively and electrically connected to the first floating diffusion region 121 and the second floating diffusion region 122. The source follower transistors 150 may include a first source follower transistor 151 and a second source follower transistor 152 that are at different locations.

In some embodiments, the first source follower transistor 151 and the selection transistor 160 may be arranged in the first sub-pixel SBP1, and the second source follower transistor 152 may be arranged in the second sub-pixel SBP2. Here, an output voltage line Vout may be connected to an end of the selection transistor 160. For example, the first source follower transistor 151 of the first shared pixel SP1 and the selection transistor 160 of the first shared pixel SP1 may face each other in the first horizontal direction (the X direction) and may be arranged on opposite sides of the first shared pixel SP1 in the first horizontal direction (the X direction), and the first source follower transistor 151 and the second source follower transistor 152 may face each other in the second horizontal direction (the Y direction) and be arranged on one side of the first shared pixel SP1 in the first horizontal direction (the X direction).

In a plan view, the contact barrier structure CAWd may have a long axis in the second horizontal direction (the Y direction) in regions where the selection transistor 160 of the first shared pixel SP1 and the output voltage line Vout face the first source follower transistor 151 of the second shared pixel SP2.

In a cross-sectional view, the contact barrier structure CAWd may overlap the deep trench isolation structure DTI in the vertical direction (the Z direction) and may be spaced apart therefrom. The lower insulating layer 102 that is an insulating material layer may be arranged between the contact barrier structure CAWd and the deep trench isolation structure DTI. A vertical level of a lower surface of the contact barrier structure CAWd may be lower than a vertical level of the lower surface of the gate structure 103 forming the source follower transistor 150. FIGS. 11A and 11B show that the contact barrier structure CAWd has substantially the same structure as the contact barrier structure CAW of FIGS. 4A and 4B, but one or more embodiments are not limited thereto. For example, the contact barrier structure CAWd may have substantially the same structure as the contact barrier structure CAWa of FIGS. 7A and 7B, the contact barrier structure CAWb of FIGS. 8A and 8B, or the contact barrier structure CAWc of FIG. 9.

The discharging wiring layer DML may electrically connect the protection diode PTD to the contact barrier structures CAWd. The pixel wiring layer ML, which is connected to the unit pixels PU, is not electrically connected to the discharging wiring layer DML, and thus, a voltage different from that applied to the unit pixels PU may be applied to the contact barrier structures CAWd.

Each of the first source follower transistor 151, the second source follower transistor 152, and the selection transistor 160 may be electrically connected to the vertical contact 107, and the vertical contact 107 may be surrounded by the upper insulating layer 105.

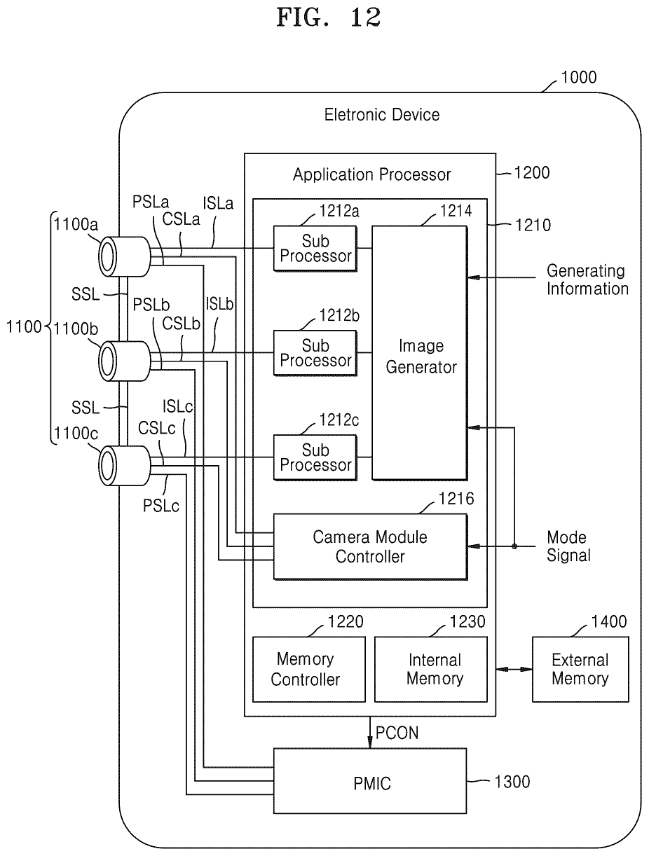

FIG. 12 is a block diagram of an electronic device including a multi-camera module including an image sensor, according to embodiments.

Referring to FIG. 12, an electronic device 1000 may include a camera module group 1100, an application processor 1200, a PMIC 1300, and a storage 1400.

The camera module group 1100 may include a plurality of camera modules 1100a to 1100c. The camera modules 1100a to 1100c may each include at least one of the image sensors 100, 100A, 100B, 100C, 100D, and 200 of FIGS. 1 to 11B. FIG. 12 shows that the camera module group 1100 includes three camera modules 1100a to 1100c, but one or more embodiments are not limited thereto. In some embodiments, the camera module group 1100 may include only one camera module, only two camera modules, or n camera modules (here, n is a natural number that is at least 4).

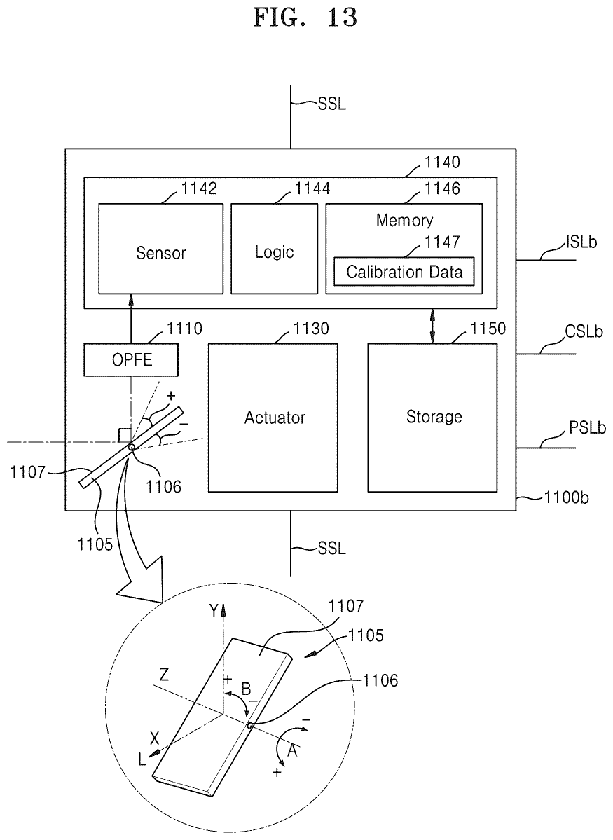

FIG. 13 is a detailed block diagram of the camera module of FIG. 12.

Referring to FIG. 13, the camera module 1100b may include a prism 1105, an optical path folding element (OPFE) 1110, an actuator 1130, an image sensing device 1140, and a storage 1150.

Here, a specific configuration of one camera module 1100b is described in more detail, but the description below may be identically applied to other camera modules 1100a and 1100c according to embodiments.

The prism 1105 may include a reflective surface 1107 of a light-reflecting material and change a path of light L that is incident from the outside. In some embodiments, the prism 1105 may change the path of light L, which is incident in a first direction (the X direction), into a path in a second direction (the Y direction) that is perpendicular to the first direction (the X direction). In addition, the prism 1105 may rotate the reflective surface 1107 of the light-reflecting material in an A direction relative to a central axis 1106 or rotate the central axis 1106 in a B direction, thus changing the path of light L, which is incident in the first direction (the X direction), into the path in the second direction (the Y direction) that is perpendicular to the first direction (the X direction). In this case, the OPFE 1110 may also move in the first direction (the X direction), the second direction (the Y direction), and a third direction (a Z direction).

In some embodiments, as shown in the drawing, the maximum rotation angle of the prism 1105 in the A direction may be 15° or less in a +A direction and greater than 15° in a −A direction, but one or more embodiments are not limited thereto.

In some embodiments, the prism 1105 may move in a range of approximately 20°, between 10° and 20°, or between 15° and 20° in either a +B direction or a −B direction, and the movement angle of the prism 1105 may be the same in the +B direction or the −B direction or nearly similar in a range of approximately 1°.

In some embodiments, the prism 1105 may move the reflective surface 1107 of the light-reflecting material in the third direction (the Z direction) parallel to the extension direction of the central axis 1106.

The OPFE 1110 may include an optical lens including, for example, m lenses (where, m is a natural number). The m lenses may move in the second direction (the Y direction) and change the optical zoom ratio of the camera module 1100b. For example, when the basic optical zoom ratio of the camera module 1100b is Z, moving the m optical lenses in the OPFE 1110 may result in a change in the optical zoom ratio of the camera module 1100b to 3Z, 5Z, or more.

The actuator 1130 may move one or more lenses of the OPFE 1110 to a specific location. For example, for accurate sensing, the actuator 1130 may adjust the position of the optical lens to make the image sensor 1142 at the focal length of the optical lens.

The image sensing device 1140 may include an image sensor 1142, a control logic 1144, and a memory 1146. The image sensing device 1140 may include at least one of the image sensors 100, 100A, 100B, 100C, 100D, and 200 of FIGS. 1 to 11B. The image sensor 1142 may sense an image of a sensing target by using light L provided through the OPFE 1110. The control logic 1144 may control general operations of the camera module 1100b. For example, the control logic 1144 may control the operation of the camera module 1100b according to a control signal provided through a control signal line CSLb.

The memory 1146 may store information, for example, calibration data 1147, which is required for the operation of the camera module 1100b. The calibration data 1147 may include information required for the camera module 1100b to generate image data by using the light L provided from the outside. The calibration data 1147 may include, for example, information regarding the degree of rotation, information regarding the focal length, information regarding the optical axis, and the like. When the camera module 1100b is realized as a multi-state camera of which the focal length changes according to the position of one or more optical lenses of the OPFE 1110, the calibration data 1147 may include information regarding a focal length value for each position (or each state) of the optical lens and auto-focus.

The storage 1150 may store image data sensed by the image sensor 1142. The storage 1150 may be arranged outside the image sensing device 1140 and implemented in a stack form along with a sensor chip forming the image sensing device 1140. In some embodiments, the storage 1150 may be realized as an electrically erasable programmable read-only memory (EEPROM), but one or more embodiments are not limited thereto.

Referring to FIGS. 12 and 13 together, each of the camera modules 1100a, 1100b, and 1100c may include the actuator 1130. Accordingly, each of the camera modules 1100a, 1100b, and 1100c may include the same or different calibration data 1147 according to the operation of the actuator 1130 therein.

In some embodiments, one camera module (e.g., the camera module 1100b) among the camera modules 1100a, 1100b, and 1100c may be of a folded lens type which includes the prism 1105 and the OPFE 1110 described above, and the others may each be a vertical camera module that does not include the prism 1105 and the OPFE 1110, but one or more embodiments are not limited thereto.

In some embodiments, one camera module (e.g., the camera module 1100c) among the camera modules 1100a, 1100b, and 1100c may be, for example, a depth camera of a vertical type which extracts depth information by using infrared rays (IR). In this case, the application processor 1200 may merge the image data, which is received from the depth camera, into image data, which is received from another camera module (e.g., the camera module 1100a or 1100b) and thus generate a 3D depth image.

In some embodiments, at least two (e.g., the camera modules 1100a and 1100b) of the camera modules 1100a to 1100c may have different fields of view. In this case, for example, at least two (e.g., the camera modules 1100a and 1100b) of the camera modules 1100a to 1100c may include different optical lenses, but one or more embodiments are not limited thereto.

In some embodiments, the fields of view of the camera modules 1100a to 1100c may be different from each other. In this case, the optical lenses included in the camera modules 1100a to 1100c may be different from each other, but one or more embodiments are not limited thereto.

In some embodiments, the camera modules 1100a to 1100c may be physically separated and arranged. That is, a sensing area of a single image sensor 1142 is not divided by the camera modules 1100a to 1100c, but instead a plurality of image sensors 1142 may be individually and respectively arranged in the camera modules 1100a to 1100c.

Referring back to FIG. 12, the application processor 1200 may include an image processor 1210, a memory controller 1220, and an internal memory 1230. The application processor 1200 may be separated from the camera modules 1100a to 1100c. For example, the application processor 1200 and the camera modules 1100a to 1100c may be realized as separate semiconductor chips.

The image processor 1210 may include a plurality of sub-image processors 1212a to 1212c, an image generator 1214, and a camera module controller 1216.

The image processor 1210 may include the sub-image processors 1212a to 1212c of which the number corresponds to the number of camera modules 1100a to 1100c.

Image data generated by camera modules 1100a to 1100c may be provided to their corresponding sub-image processors 1212a to 1212c through separate image signal lines ISLa to ISLc, respectively. For example, the image data generated by the camera module 1100a may be provided to the sub-image processor 1212a through the image signal line ISLa, the image data generated by the camera module 1100b may be provided to the sub-image processor 1212b through the image signal line ISLb, and the image data generated by the camera module 1100c may be provided to the sub-image processor 1212c through the image signal line ISLc. The transmission of the image data may be performed using a camera serial interface (CSI) based on a mobile industry processor interface (MIPI), but one or more embodiments are not limited thereto.

In some embodiments, one sub-image processor may be arranged to correspond to multiple camera modules. For example, the sub-image processors 1212a and 1212c may be integrated into one sub-image processor instead of separate sub-image processors as illustrated, and the image data provided from the camera modules 1100a and 1100c may be selected by a selection device (e.g., a multiplexer) and then provided to the integrated sub-image processor.

The image data provided to each of the sub-image processors 1212a to 1212c may be provided to the image generator 1214. The image generator 1214 may generate an output image by using the image data provided from each of the sub-image processors 1212a to 1212c, according to image generating information or a mode signal.

In detail, the image generator 1214 may generate the output image by merging at least some of the image data generated by the camera modules 1100a to 1100c with different fields of view, according to the image generating information or the mode signal. In addition, the image generator 1214 may select any one of the image data generated by the camera modules 1100a to 1100c with different fields of view and may generate the output image, according to the image generating information or the mode signal.

In some embodiments, the image generating information may include a zoom signal (or a zoom factor). Also, in some embodiments, the mode signal may be, for example, a signal based on a mode selected by a user.

When the image generating information is a zoom signal (or a zoom factor) and the camera modules 1100a to 1100c have different fields of view (viewing angles), the image generator 1214 may perform different operations depending on types of zoom signals. For example, when the zoom signal is a first signal, an output image may be generated by merging the image data from the camera module 1100a with the image data from the camera module 1100c and then using a merged image signal and the image data that is not used for the merging and output from the camera module 1100b. When the zoom signal is a second signal that is different from the first signal, the image generator 1214 may not perform the above image data merging and select any one of the image data respectively output from the camera modules 1100a to 1100c, thereby generating the output image. However, one or more embodiments are not limited thereto, and according to necessity, a method of processing the image data may be variously modified and implemented.

In some embodiments, the image generator 1214 may receive multiple pieces of image data, of which exposure durations are different, from at least one of the sub-image processors 1212a to 1212c and perform HDR processing on the pieces of image data, thereby generating merged image data with an increased dynamic range.

The camera module controller 1216 may provide control signals to the camera modules 1100a to 1100c, respectively. The control signals generated by the camera module controller 1216 may be provided to corresponding camera modules 1100a to 1100c through separate control signal lines CSLa to CSLc.

Any one of the camera modules 1100a to 1100c may be designated as a master camera module (e.g., the camera module 1100b) according to the image generating information or the mode signal that includes the zoom signal, and the remaining camera modules (e.g., the camera modules 1100a and 1100c) may be designated as slave cameras. Such information may be included in the control signals and provided to corresponding camera modules 1100a to 1100c through the separate control signal lines CSLa to CSLc.

The camera modules functioning as a master and slaves may change according to a zoom factor or an operation mode signal. For example, when the viewing angle of the camera module 1100a is greater than the viewing angle of the camera module 1100b and the zoom factor indicates a low zoom ratio, the camera module 1100b may function as a master and the camera module 1100a may function as a slave. On the other hand, when the zoom factor indicates a high zoom ratio, the camera module 1100a may function as a master, and the camera module 1100b may function as a slave.

In some embodiments, the control signals provided to each of the camera modules 1100a to 1100c from the camera module controller 1216 may include a sync enable signal. For example, when the camera module 1100b is a master camera and the camera modules 1100a and 1100c are slave cameras, the camera module controller 1216 may transmit the sync enable signal to the camera module 1100b. The camera module 1100b receiving the above sync enable signal may generate a sync signal based on the provided sync enable signal and may provide the generated sync signal to the camera modules 1100a and 1100c through a sync signal line SSL. The camera module 1100b and the camera modules 1100a and 1100c may be synchronized with the sync signal and transmit the image data to the application processor 1200.

In some embodiments, the control signals provided from the camera module controller 1216 to the camera modules 1100a to 1100c may include mode information according to the mode signal. Based on mode information, the camera modules 1100a to 1100c may operate in a first operation mode and a second operation mode, in relation to sensing speed.

In the first operation mode, the camera modules 1100a to 1100c may generate image signals at a first speed (for example, generate image signals at a first frame rate), encode the image signals at a second speed higher than the first speed (for example, encode the image signals at a second frame rate higher than the first frame rate), and then transmit the encoded image signals to the application processor 1200.

The application processor 1200 may store received image signals, that is, the encoded image signals, in the memory 1230 therein or the storage 1400 outside the application processor 1200, read and decode the encoded image signals from the memory 1230 or the storage 1400, and thus display image data generated based on the decoded image signals. For example, a corresponding sub-image processor among the sub-image processors 1212a to 1212c of the image processor 1210 may perform decoding and also perform image processing on the decoded image signals.

In the second operation mode, the camera modules 1100a to 1100c may generate image signals at a third speed lower than the first speed (for example, generate image signals at a third frame rate lower than the first frame rate) and transmit the image signals to the application processor 1200. The image signals provided to the application processor 1200 may be signals that are not encoded. The application processor 1200 may perform image processing on the received image signals or store the image signals in the memory 1230 or the storage 1400.

The PMIC 1300 may respectively supply the camera modules 1100a to 1100c with power, for example, the power voltage. For example, the PMIC 1300 may supply first power to the camera module 1100a through a power signal line PSLa, second power to the camera module 1100b through a power signal line PSLb, and third power to the camera module 1100c through a power signal line PSLc, under the control of the application processor 1200.

The PMIC 1300 may generate power corresponding to each of the camera modules 1100a to 1100c and adjust a power level, in response to a power control signal PCON from the application processor 1200. The power control signal PCON may include a power adjusting signal for each operation mode of the camera modules 1100a to 1100c. For example, the operation mode may include a low-power mode, and in this case, the power control signal PCON may include information regarding a camera module operating in the low-power mode and a set level of power. The level of power supplied to each of the camera modules 1100a to 1100c may be identical or different. In addition, the level of power may dynamically change.

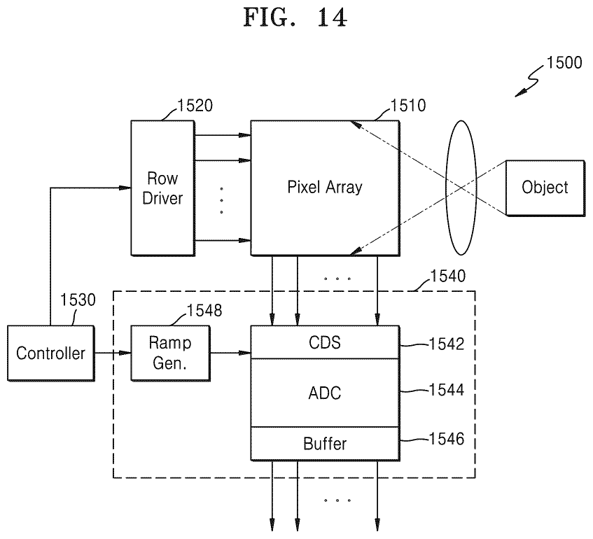

FIG. 14 is a block diagram showing a configuration of an image sensor, according to embodiments.

Referring to FIG. 14, an image sensor 1500 may include a pixel array 1510, a controller 1530, a row driver 1520, and a pixel signal processor 1540.

The image sensor 1500 may include at least one of the image sensors 100, 100A, 100B, 100C, 100D, and 200 of FIGS. 1 to 11B. The pixel array 1510 may include a plurality of unit pixels two-dimensionally arranged, and each unit pixel may include a photoelectric transformation element. The photoelectric transformation element may generate photo charges by absorbing light, and an electrical signal (an output voltage) according to the generated photo charges may be provided to the pixel signal processor 1540 through a vertical signal line.

The unit pixels included in the pixel array 1510 may provide the output voltage one by one in units of rows, and accordingly, the unit pixels included in one row of the pixel array 1510 may be simultaneously activated by a selection signal output from the row driver 1520. The unit pixels included in the selected row may supply an output voltage according to the absorbed light to an output line of a corresponding column.

The controller 1530 may control the row driver 1520 to enable the pixel array 1510 to accumulate photo charges by absorbing light or temporarily store the accumulated photo charges and output an electrical signal according to the stored photo charges to the outside of the pixel array 1510. In addition, the controller 1530 may control the pixel signal processor 1540 to measure the output voltage supplied by the pixel array 1510.

The pixel signal processor 1540 may include a correlated double sampler 1542, an analog-to-digital converter 1544, and a buffer 1546. The correlated double sampler 1542 may sample and hold the output voltage supplied by the pixel array 1510.

The correlated double sampler 1542 may doubly sample a specific noise level and a level according to the generated output voltage and thus output a level corresponding to the difference therebetween. Also, the correlated double sampler 1542 may receive and compare ramp signals generated by a ramp signal generator 1548 and output a comparison result.

The analog-to-digital converter 1544 may convert analog signals, which correspond to the levels transmitted from the correlated double sampler 1542, into digital signals. The buffer 1546 may latch the digital signals, and the latched signals may be sequentially transmitted to the outside of the image sensor 1500 and thus to an image processor (not shown).

While the inventive concept has been particularly shown and described with reference to embodiments thereof, it will be understood that various changes in form and details may be made therein without departing from the spirit and scope of the disclosure.

What is claimed is:

1. An image sensor comprising:
a substrate comprising a pixel region, a through electrode region, and a power supply region between the pixel region and the through electrode region;
a plurality of through electrodes in the through electrode region;
a plurality of shared pixels separated from each other by a first trench isolation structure in the pixel region, each shared pixel of the plurality of shared pixels comprising a plurality of unit pixels, wherein the first trench isolation structure extends in the substrate in a vertical direction;
a plurality of contact barriers between the plurality of shared pixels and overlapping the first trench isolation structure in the vertical direction; and
a protection diode in the power supply region, the protection diode comprising a first impurity region where first power is supplied by any one of the plurality of through electrodes, and the protection diode being electrically connected to the plurality of contact barriers,
wherein, in a plan view, between a first shared pixel and a second shared pixel that are adjacent to each other among the plurality of shared pixels, each of the plurality of contact barriers is arranged between a first source follower gate of the first shared pixel and a second source follower gate of the second shared pixel.

2. The image sensor of claim 1, wherein
the first shared pixel and the second shared pixel are arranged adjacent to each other in a first horizontal direction, and
each of the plurality of contact barriers has a long axis in a second horizontal direction that is perpendicular to the first horizontal direction.

3. The image sensor of claim 2, further comprising:
a pixel wiring layer configured to electrically connect the plurality of unit pixels to each other; and
a discharging wiring layer configured to electrically connect the plurality of contact barriers to the protection diode,
wherein the pixel wiring layer is not electrically connected to the discharging wiring layer.

4. The image sensor of claim 3, wherein the discharging wiring layer extends in the first horizontal direction.

5. The image sensor of claim 1, further comprising:
a second impurity region in the power supply region and in which second power is supplied by another one of the plurality of through electrodes; and
a third impurity region in the pixel region and electrically connected to the second impurity region,
wherein the first impurity region and the second impurity region comprise impurities of different conductive types from each other.

6. The image sensor of claim 5, further comprising, in the power supply region,
a second trench isolation structure that vertically extends in the substrate and separates the first impurity region from the second impurity region.

7. The image sensor of claim 5, wherein the first power is different from the second power.

8. The image sensor of claim 5, wherein
the first impurity region is an n-type impurity region comprising n-type impurities, and each of the second impurity region and the third impurity region is a p-type impurity region comprising p-type impurities.

9. The image sensor of claim 1, further comprising:
a first vertical contact connected to the first source follower gate; and
a second vertical contact connected to the second source follower gate,
wherein the plurality of contact barriers comprise the same material as the first vertical contact and the second vertical contact.

10. The image sensor of claim 1, wherein the first trench isolation structure is spaced apart from the plurality of contact barriers in the vertical direction.

11. An image sensor comprising:
a substrate comprising a pixel region, a through electrode region, and a power supply region between the pixel region and the through electrode region;
a plurality of through electrodes in the through electrode region;
a plurality of shared pixels separated from each other by a first trench isolation structure in the pixel region, each shared pixel of the plurality of shared pixels comprising a plurality of unit pixels, wherein the first trench isolation structure extends in the substrate in a vertical direction;
a plurality of contact barriers between the plurality of shared pixels and overlapping the first trench isolation structure in the vertical direction; and
a protection diode in the power supply region, the protection diode comprising a first impurity region where first power is supplied by any one of the plurality of through electrodes, and the protection diode being electrically connected to the plurality of contact barriers,
wherein the plurality of shared pixels comprise a first shared pixel and a second shared pixel that are adjacent to each other, and each of the first shared pixel and the second shared pixel comprises a plurality of floating diffusion regions at different locations from each other and a plurality of source follower gates that are electrically connected to the plurality of floating diffusion regions, the plurality of source follower gates being arranged at different locations from each other, and
in a plan view, each of the plurality of contact barriers is between one of the plurality of source follower gates of the first shared pixel and one of the plurality of source follower gates of the second shared pixel which face each other.

12. The image sensor of claim 11, wherein
the first shared pixel and the second shared pixel are arranged adjacent to each other in a first horizontal direction,
for each of the first shared pixel and the second shared pixel:
the plurality of source follower gates comprise a first source follower gate, a second source follower gate, and a third source follower gate,
the first source follower gate and the second source follower gate face each other in the first horizontal direction and are arranged on opposite sides of the shared pixel in the first horizontal direction,
on one side of the shared pixel in the first horizontal direction, the first source follower gate and the third source follower gate face each other in a second horizontal direction that is perpendicular to the first horizontal direction, and
each of the plurality of contact barriers is arranged between the second source follower gate of the first shared pixel and the first source follower gate and the third source follower gate of the second shared pixel.

13. The image sensor of claim 12, wherein
each of the plurality of contact barriers has a long axis in the second horizontal direction perpendicular to the first horizontal direction, and
the plurality of contact barriers are electrically connected to each other by a discharging wiring layer extending in the first horizontal direction.

14. The image sensor of claim 11, further comprising:
a second impurity region in the power supply region and in which second power is supplied by another one of the plurality of through electrodes, wherein the second power is different from the first power;
a third impurity region in the pixel region and electrically connected to the second impurity region; and
in the power supply region, a second trench isolation structure extending in the substrate in the vertical direction and separating the first impurity region from the second impurity region.

15. The image sensor of claim 14, wherein the first impurity region is an n-type impurity region comprising n-type impurities, and the second impurity region is a p-type impurity region comprising p-type impurities.

16. The image sensor of claim 11, wherein
the first shared pixel and the second shared pixel are adjacent to each other in a first horizontal direction,
each of the first shared pixel and the second shared pixel comprises a first floating diffusion region, a second floating diffusion region, a first source follower gate, a second source follower gate, and a selection gate,
for each of the first shared pixel and the second shared pixel, the first source follower gate and the second source follower gate face each other in a second horizontal direction that is perpendicular to the first horizontal direction and are on one side of each of the first shared pixel and the second shared pixel in the first horizontal direction,
the selection gate of the first shared pixel faces, in the first horizontal direction, the first source follower gate of the second shared pixel on the other side of the first shared pixel in the horizontal direction, and
the plurality of contact barriers have long axes in the second horizontal direction between the selection gate of the first shared pixel and the first source follower gate of the second shared pixel.

17. The image sensor of claim 16, wherein
the plurality of contact barriers are electrically connected to each other by a discharging wiring layer extending in the first horizontal direction,
in each of the first shared pixel and the second shared pixel, the first floating diffusion region, the second floating diffusion region, the first source follower gate, and the second source follower gate are electrically connected to each other by a pixel wiring layer, and
the pixel wiring layer is not electrically connected to the discharging wiring layer.

18. An image sensor comprising:
a substrate comprising a pixel region, a through electrode region, and a power supply region between the pixel region and the through electrode region;
a plurality of shared pixels comprising, in the pixel region, a first shared pixel and a second shared pixel which are adjacent to each other in a first horizontal direction, wherein each of the first shared pixel and the second shared pixel comprises a first source follower gate, a second source follower gate, a third source follower gate, a first sub-pixel with four first unit pixels sharing a first floating diffusion region, and a second sub-pixel with four second unit pixels sharing a second floating diffusion region;
a first trench isolation structure in the substrate and configured to divide the plurality of shared pixels in the pixel region;
a plurality of through electrodes in the through electrode region;
a plurality of contact barriers having long axes in a second horizontal direction perpendicular to the first horizontal direction, the plurality of contact barriers being between the plurality of shared pixels, and the plurality of contact barriers overlapping the first trench isolation structure in a vertical direction; and
a protection diode arranged in the power supply region, the protection diode comprising a first impurity region where first power is supplied by any one of the plurality of through electrodes, and the protection diode being electrically connected to the plurality of contact barriers,
wherein, in each of the first shared pixel and the second shared pixel, the first source follower gate and the second source follower gate face each other in the first horizontal direction and are on opposite sides of each of the first shared pixel and the second shared pixel in the first horizontal direction, and the first source follower gate and the third source follower gate face each other in the second horizontal direction and are on one side of each of the first shared pixel and the second shared pixel in the first horizontal direction, and
each of the plurality of contact barriers is between the second source follower gate of the first shared pixel and the first source follower gate and the third source follower gate of the second shared pixel.

19. The image sensor of claim 18, further comprising:
a second impurity region in the power supply region and in which second power is supplied by another one of the plurality of through electrodes, wherein the second power is different from the first power;
a third impurity region in the pixel region and electrically connected to the second impurity region; and
a second trench isolation structure extending in the substrate in the vertical direction and separating the first impurity region from the second impurity region, in the power supply region,
wherein the first impurity region is an n-type impurity region comprising n-type impurities, and each of the second impurity region and the third impurity region is a p-type impurity region comprising p-type impurities.

20. The image sensor of claim 18, wherein
in each of the first shared pixel and the second shared pixel:
the first source follower gate and the second source follower gate are in the first sub-pixel,
the third source follower gate is in the second sub-pixel,
the first floating diffusion region, the second floating diffusion region, the first source follower gate, the second source follower gate, and the third source follower gate are electrically connected to one another by a pixel wiring layer, and
the plurality of contact barriers are electrically connected to each other by a discharging wiring layer that is not electrically connected to the pixel wiring layer.
